(19) United States
(12) Patent Application Publication
(10) Pub. No.: US 2026/0243968 A1
(43) Pub. Date: Aug. 20, 2026

(54) OPTICAL CIRCUIT SWITCH

(71) Applicant: Lumentum Operations LLC, San Jose, CA (US)

(72) Inventors: Sheldon MCLAUGHLIN, Ottawa (CA); Joel MILGRAM, Ottawa (CA); Paul Dwight COLBOURNE, Ottawa (CA)

(21) Appl. No.: 19/194,297

(22) Filed: Apr. 30, 2025

Related U.S. Application Data
(60) Provisional application No. 63/758,694, filed on Feb. 14, 2025.

(51) Int. Cl. G02B 6/35

(52) U.S. Cl. CPC G02B 6/359; G02B 6/3546; G02B 6/3548

(57) ABSTRACT

In some implementations, an OCS includes a first array of optical ports arranged in a first pattern, a first array of beam steering elements arranged in a second pattern, and a first set of optical elements positioned between the first array of optical ports and the first array of beam steering elements. The first array of optical ports are optically coupled to the first array of beam steering elements by the first set of optical elements. A particular pattern of the first pattern and the second pattern is a non-periodic pattern. Another particular pattern of the first pattern and the second pattern is a periodic pattern.

### CROSS-REFERENCE TO RELATED APPLICATION

This Patent Application claims priority to U.S. Patent Application No. 63/758,694, filed on Feb. 14, 2025, and entitled “OPTICAL CIRCUIT SWITCH.” The disclosure of the prior Application is considered part of and is incorporated by reference into this Patent Application.

### TECHNICAL FIELD

The present disclosure relates generally to an optical device and to an optical circuit switch (OCS).

### BACKGROUND

In an optical communication network, optical signals having a plurality of optical channels at individual wavelengths (typically called “wavelength channels”) are transmitted from one location to another, typically through a length of optical fiber. An OCS is a type of optical switch that allows switching of optical signals from one optical fiber to another.

### SUMMARY

In some implementations, an OCS includes a first array of optical ports arranged in a first pattern; a first array of beam steering elements arranged in a second pattern; and a first set of optical elements positioned between the first array of optical ports and the first array of beam steering elements, wherein: the first array of optical ports are optically coupled to the first array of beam steering elements by the first set of optical elements, a particular pattern of the first pattern and the second pattern is a non-periodic pattern, and another particular pattern of the first pattern and the second pattern is a periodic pattern.

In some implementations, an optical switch includes an array of optical ports arranged in a first pattern; and an array of beam steering elements arranged in a second pattern, wherein: the array of optical ports are optically coupled to the array of beam steering elements, a particular pattern of the first pattern and the second pattern is a non-periodic pattern, and another particular pattern of the first pattern and the second pattern is a periodic pattern.

In some implementations, an optical device includes an array of optical ports; and an array of beam steering elements optically coupled to the array of optical ports, wherein: one array of the array of optical ports and the array of beam steering elements is arranged in a non-periodic pattern, and another array of the array of optical ports and the array of beam steering elements is arranged in a periodic pattern.

### BRIEF DESCRIPTION OF THE DRAWINGS

FIGS. 1A-1B are diagrams of example implementations of an OCS.

FIGS. 2A-2B are diagrams of example implementations associated with the OCS.

### DETAILED DESCRIPTION

The following detailed description of example implementations refers to the accompanying drawings. The same reference numbers in different drawings may identify the same or similar elements.

An OCS is a type of optical switch that routes beams (e.g., optical beams). An OCS can include an input fiber array and an output fiber array, each paired with a corresponding array of beam-forming elements (e.g., collimators). A first array of beam steering elements (e.g., mirrors, such as micro-electromechanical systems (MEMS) mirrors) is associated with the input fiber array, and a second array of beam steering elements is associated with the output fiber array. By configuring beam steering elements in both arrays of beam steering elements, a beam from any input fiber can be directed to an output fiber, enabling flexible optical switching.

When the arrays of beam steering elements are oriented at a non-zero angle to an optical axis of the OCS (e.g., to minimize a required beam steering angle) and, optionally, a set of optical elements (e.g., lenses) modify directions of beams that propagate via the OCS, spacing variations are introduced to the beams. As an example, when beams exit from the input fiber array, in which optical ports are arranged in a periodic pattern (e.g., in a 2-dimensional regular array), the beams, because of a non-zero angle orientation of the first array of beam steering elements and because a first set of optical elements converge the beams that exit from the input fiber array on the first array of beam steering elements, ultimately impinge on the first array of beam steering elements in a non-periodic pattern (e.g., with non-uniform spacing between beams). This can impact a functionality of the first array of beam steering elements arranged in a corresponding periodic pattern. For example, a beam may not impinge on an intended beam steering element of the first array of beam steering elements, or only a portion of the beam may impinge on the intended beam steering element, and thus the beams may not be steered as intended by the first array of beam steering elements. At least some of the beams may therefore not be directed to correct output fibers of the output fiber array, which impacts a functionality of the OCS.

Some implementations described herein include an OCS (or another type of optical switch or optical device). The OCS may be, for example, non-blocking, blocking, or partially non-blocking. The OCS comprises a first array of optical ports that are optically coupled to a first array of beam steering elements. In some implementations, a first array of beam-forming elements and/or a first set of optical elements may be disposed between the first array of optical ports and the first array of beam steering elements. The first array of optical ports are arranged in a first pattern and the first array of beam of steering elements are arranged in a second pattern. A particular pattern of the first pattern and the second pattern is a non-periodic pattern, while another particular pattern of the first pattern and the second pattern is a periodic pattern. A non-periodic pattern has a non-uniform spacing (e.g., non-uniform spacing or pitch between elements) in at least one direction. A periodic pattern has respective uniform periodicities (e.g., a uniform spacing or pitch between elements) in at least two directions. In some implementations the OCS also comprises a second array of optical ports arranged in the first pattern or a different, third pattern, and a second array of beam steering elements arranged in the second pattern or a different, fourth pattern, that are optically coupled to each other. A particular pattern of the third pattern and the fourth pattern is a non-periodic pattern, while another particular pattern of the third pattern and the fourth pattern is a periodic pattern. A second array of beam-forming elements and/or a second set of optical elements may be disposed between the second array of optical ports and the second array of beam steering elements.

A principal axis of each array of beam steering elements is oriented at a non-zero angle with respect to an optical axis of the OCS, which (in association with a corresponding set of optical elements) introduces spacing variations to a set of beams that propagate through the OCS. Notably, the OCS compensates for the spacing variations by arranging each array of optical ports in the first pattern (or in the first pattern and the third pattern, respectively) and each array of beam steering elements in the second pattern (or in the second pattern and the fourth pattern, respectively). Accordingly, each optical port in the first array of optical ports provides a beam to a respective beam steering element in the first array of beam steering elements, on a one-to-one basis. Similarly, each optical port in the second array of optical ports receives a beam from a respective beam steering element in the second array of beam steering elements, on a one-to-one basis.

In this way, some implementations improve a functionality of the OCS. For example, a beam that emits from an optical port of the first array of optical ports has an improved likelihood of impinging on an intended beam steering element (e.g., with more than a threshold portion of the beam impinging on the intended beam steering element) of the first array of beam steering elements. This enables the beam to be steered as intended by the first array of beam steering elements, such as to an intended beam steering element of the second array of beam steering elements. Similarly, the second array of beam steering elements is able to steer the beam to an intended optical port (e.g., a correct optical port) of the second array of optical ports.

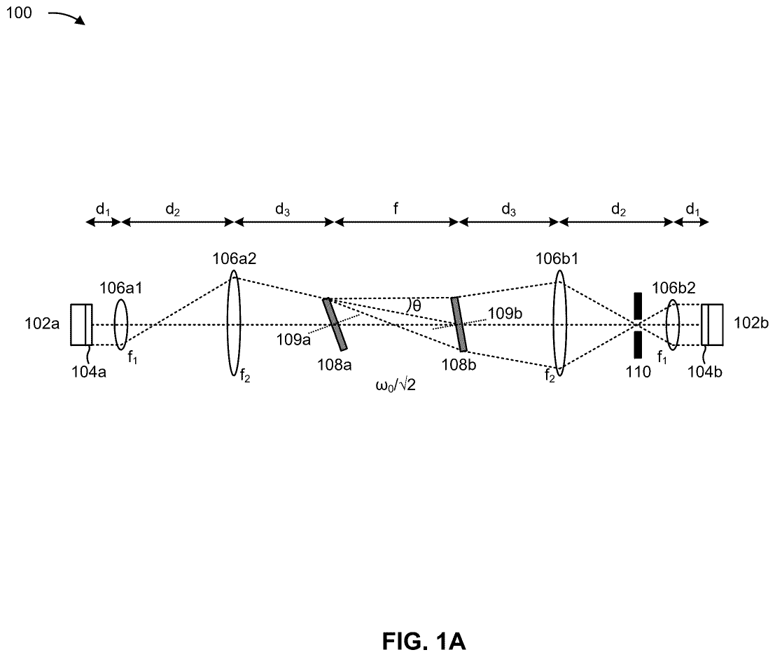

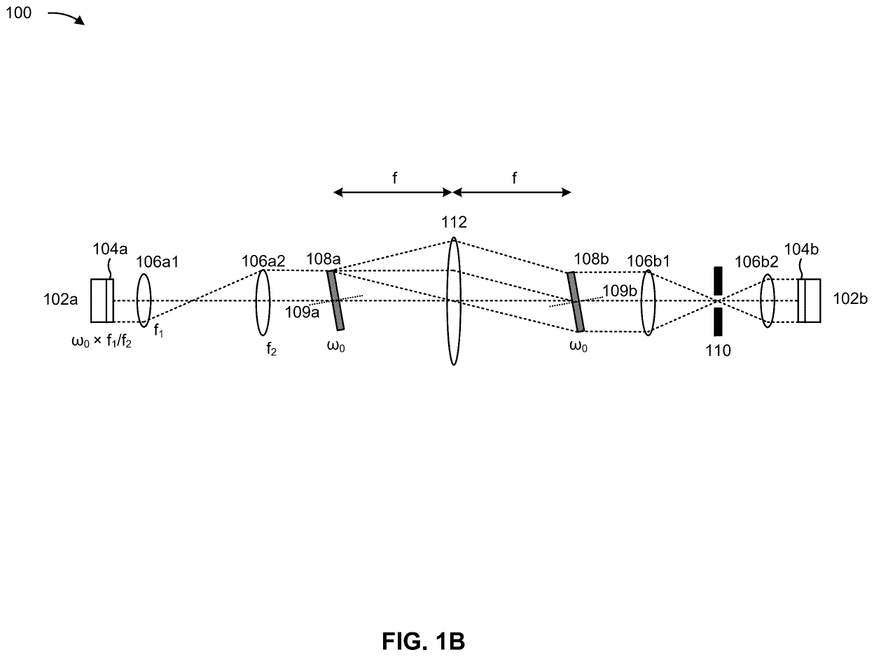

FIGS. 1A-1B are diagrams of example implementations of an OCS 100. For clarity, elements of the OCS 100 are shown as transmissive components (e.g., in an unfolded optical layout). Accordingly, FIGS. 1A-1B depict an optical axis of the OCS 100 (e.g., that is aligned with a horizontal direction) in a linear, unfolded orientation. In a physical implementation, any one or more of the elements along the optical path of the OCS 100 may be configured to deflect or reflect the optical path to fold or multiply-fold the optical path of the OCS 100.

As shown in FIG. 1A, in a first example implementation, the OCS 100 comprises a first array of optical ports 102a, a first array of beam-forming elements 104a, a first set of optical elements 106a (e.g., including an optical element 106a1 and an optical element 106a2), a first array of beam steering elements 108a, a second array of beam steering elements 108b, a second set of optical elements 106b (e.g., including an optical element 106b1 and an optical element 106b2), a second array of beam-forming elements 104b, and a second array of optical ports 102b. As further shown in FIG. 1A, the OCS 100 optionally includes an aperture element 110.

Parameters associated with the elements of the OCS 100 include a focal length f1 (e.g., a focal length of the optical element 106a1, a focal length of the optical element 106b2), a focal length f2 (e.g., a focal length of the optical element 106a2, a focal length of the optical element 106b1), a distance d1 (e.g., a distance between the first array of beam-forming elements 104a and the optical element 106a1, a distance between the optical element 106b2 and the second array of beam-forming elements 104b), a distance d2 (e.g., a distance between the optical element 106a1 and the optical element 106a2, a distance between the optical element 106b1 and the optical element 106b2), a distance d3 (e.g., a distance between the optical element 106a2 and the first array of beam steering elements 108a, a distance between the second array of beam steering elements 108b and the optical element 106b1), and a distance f (e.g., a distance between the first array of beam steering elements 108a and the second array of beam steering elements 108b). Elements of the OCS 100 are further described below, followed by an example of an operation of the OCS 100.

An array of optical ports 102 is a fiber array to couple beams (e.g., optical beams) to the OCS 100 or to couple beams from the OCS 100. For example, in some implementations, the first array of optical ports 102a may be an input fiber array unit (FAU) that couples beams to the OCS 100 (e.g., from a set of input optical fibers), while the second array of optical ports 102b may be an output FAU that couples beams out of the OCS 100 (e.g., to a set of output optical fibers). In such an implementation, the first array of optical ports 102a provides the set of beams to the first array of beam-forming elements 104a and the second array of optical ports 102b receives the set of beams after collimation, focusing, or another type of beam-forming, by the second array of beam-forming elements 104b (e.g., the beams propagate left-to-right with respect to FIG. 1).

An array of beam-forming elements 104 is an array of elements to collimate, or to perform another type of beam-forming of, the set of beams propagating through the OCS 100. For example, the first array of beam-forming elements 104a may comprise a first microlens array (MLA) including an array of microlenses to collimate the set of beams provided by the first array of optical ports 102a, while the second array of beam-forming elements 104b may comprise a second MLA including an array of microlenses to focus the set of beams to be provided to the second array of optical ports 102b (e.g., after direction by the second array of beam steering elements 108b).

A set of optical elements 106 comprises one or more optical elements to modify a direction of the set of beams propagating through the OCS 100. For example, the first set of optical elements 106a (e.g., the optical element 106a1 and the optical element 106a2) may comprise a first set of lenses that serve to converge the set of beams on the first array of beam steering elements 108a. As another example, the second set of optical elements 106b (e.g., the optical element 106b1 and the optical element 106b2) may comprise a second set of lenses that serve to converge the set of beams on the second array of beam-forming elements 104b. In some implementations, a given set of optical elements 106 may include one or more lenses (e.g., as shown in FIG. 1A). Additionally, or alternatively, a given set of optical elements 106 may include one or more curved mirrors or another type of optical element capable of modifying a direction of the set of beams.

An array of beam steering elements 108 comprises an array of adjustable elements to direct (i.e., steer) the set of beams within the OCS 100. For example, the first array of beam steering elements 108a may comprise an array of beam steering elements associated with directing each beam in the set of beams toward the second array of beam steering elements 108b.

In some implementations, the first array of beam steering elements 108a comprises multiple independent beam steering elements to direct beams in the set of beams independently. Similarly, the second array of beam steering elements 108b may comprise multiple independent beam steering elements to direct the beams in the set of beams independently. That is, each of the first array of beam steering elements 108 and the second array of beam steering elements 108 may comprise multiple independent beam steering elements to direct beams in the set of beams independently. In some implementations, an array of beam steering elements 108 (e.g., the first array of beam steering elements 108a, the second array of beam steering elements 108b) may comprise an array of tiltable MEMS mirrors, where each tiltable MEMS mirror can be used to direct one or more beams incident thereon.

In some implementations, an array of optical ports 102 is optically coupled to an array of beam-forming elements 104 (e.g., the first array of optical ports 102a is optically coupled to the first array of beam-forming elements 104a, the second array of optical ports 102b is optically coupled to the second array of beam-forming elements 104b). Further, an array of beam-forming elements 104 is optically coupled to an array of beam steering elements 108 (e.g., the first array of beam-forming elements 104a is optically coupled to the first array of beam steering elements 108a, the second array of beam-forming elements 104b is optically coupled to the second array of beam steering elements 108b). Accordingly, an array of optical ports 102 is optically coupled to an array of beam steering elements 108 by an array of beam-forming elements 104 (e.g., the first array of optical ports 102a is optically coupled to the first array of beam steering elements 108a by the first array of beam-forming elements 104a, the second array of optical ports 102b is optically coupled to the second array of beam steering elements 108b by the second array of beam-forming elements 104b). In some implementations, the first array of beam steering elements 108a is optically coupled to the second array of beam steering elements 108b.

In some implementations, a set of optical elements 106 is in a region of optical coupling between an array of beam-forming elements 104 and an array of beam steering elements 108 (e.g., the first set of optical elements 106a is in a region of optical coupling between the first array of beam-forming elements 104a and the first array of beam steering elements 108a, the second set of optical elements 106b is in a region of optical coupling between the second array of beam-forming elements 104b and the second array of beam steering elements 108b). Accordingly, an array of optical ports 102 is optically coupled to an array of beam steering elements 108 by an array of beam-forming elements 104 and the set of optical elements 106 (e.g., the first array of optical ports 102a is optically coupled to the first array of beam steering elements 108a by the first array of beam-forming elements 104a and the first set of optical elements 106a, the second array of optical ports 102b is optically coupled to the second array of beam steering elements 108b by the second array of beam-forming elements 104b and the second set of optical elements 106b).

The aperture element 110 is an optional element to reduce cross-talk between beams propagating through the OCS 100. In some implementations, as shown in FIG. 1A, the aperture element 110 may be arranged in a region of optical coupling between the second array of beam steering elements 108b and the second array of beam-forming elements 104b. In some implementations, the aperture element 110 may be arranged at a location at which all beams in the set of beams intersect. In this way, the aperture element 110 can reduce cross-talk between beam paths, particularly during switch reconfiguration operations. For example, during a switch reconfiguration operation, beams incident on intermediate, already-configured beam steering elements in the second array of beam steering elements 108b while beam steering elements in the first array of beam steering elements 108a are being reconfigured would be incident on the aperture element 110 at an off-axis location. These beams would therefore be blocked by the aperture element 110 (e.g., such that these beams are not incident on the second array of beam-forming elements 104b), meaning that cross-talk is avoided. In some implementations, a second aperture element 110 can be arranged in a region of optical coupling between the first array of beam-forming elements 104a and the first array of beam steering elements 108a, such as when the OCS 100 is a bi-directional OCS.

In some implementations, an array of optical ports 102 (e.g., the first array of optical ports 102a, the second array of optical ports 102b) may be arranged in a first pattern and an array of beam steering elements 108 (e.g., the first array of beam steering elements 108a, the second array of beam steering elements 108b) may be arranged in a second pattern. In some implementations, the first pattern does not match (e.g., is not equal to, in spacing, arrangement, or scale) the second pattern. For example, a particular pattern of the first pattern and the second pattern may be a non-periodic pattern and another particular pattern of the first pattern and the second pattern may be a periodic pattern.

A non-periodic pattern has a non-uniform spacing (e.g., non-uniform spacing or pitch between elements) in at least one direction. For example, the non-periodic pattern may have a uniform spacing in a first direction and a non-uniform spacing in a second direction (e.g., a direction that is different than the first direction, such as perpendicular to the first direction). As another example, the non-periodic pattern may have a first non-uniform spacing in a first direction and a second non-uniform spacing (e.g., that is the same as or different than the first non-uniform spacing) in a second direction (e.g., a direction that is different than the first direction, such as perpendicular to the first direction). A periodic pattern has respective uniform spacings (e.g., a uniform spacing or pitch between elements) in at least two directions. For example, the periodic pattern may have a first uniform spacing in a first direction and a second uniform spacing (e.g., that is the same as or different than the first uniform spacing) in a second direction (e.g., a direction that is different than the first direction, such as perpendicular to the first direction).

A pattern has a uniform spacing in a direction when spacings between any two adjacent elements in the direction are the same or are substantially the same (e.g., are the same within a tolerance, such as within 1%, 2%, or 3% of an average spacing between all adjacent elements in the direction). Further, a pattern has a non-uniform spacing in a direction when spacings between any two adjacent elements in the direction are not the same or are not substantially the same (e.g., a difference between spacings is greater than the tolerance).

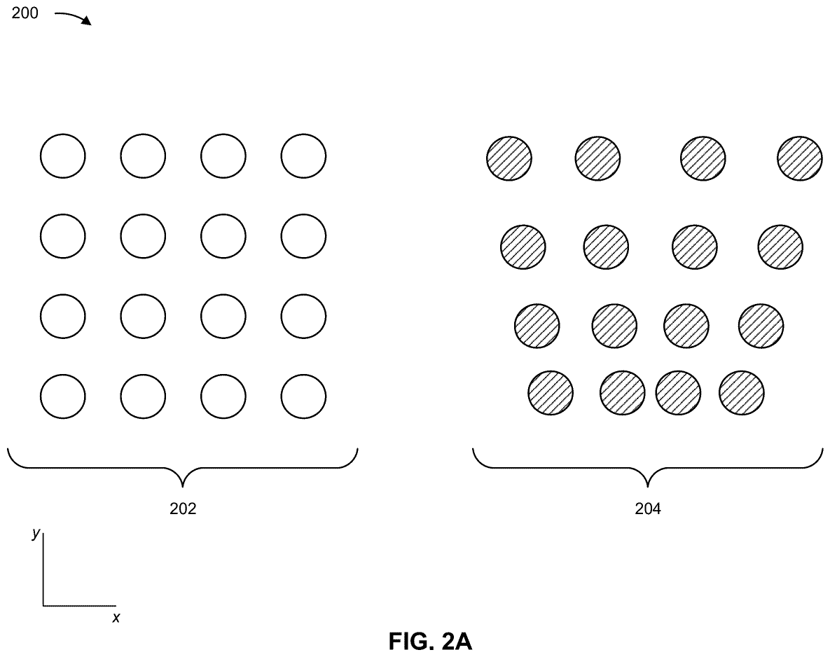

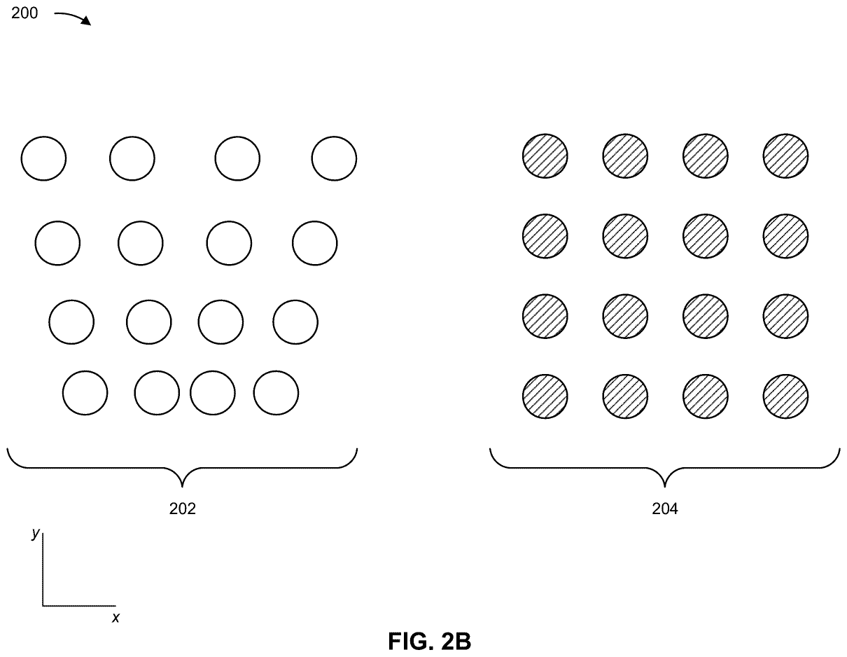

Accordingly, a non-periodic pattern may have a non-uniform spacing in a particular direction, and a periodic pattern may have a uniform spacing in the particular direction. Additionally, or alternatively, a non-periodic pattern may have respective non-uniform spacings in a plurality of directions, and a periodic pattern may have respective uniform spacings in the plurality of directions. Further description related to periodic patterns and non-periodic patterns is provided herein in relation to FIGS. 2A-2B.

In some implementations, an array of beam-forming elements 104 may be arranged in a pattern that matches the first pattern. Thus, each optical port in the first array of optical ports 102a provides light to a respective beam-forming element in the first array of beam-forming elements 104a, on a one-to-one basis. Similarly, each optical port in the second array of optical ports 102b receives light from a respective beam-forming element in the second array of beam-forming elements 104b, on a one-to-one basis.

As shown in FIG. 1A, a principal axis 109 (e.g., a rectilinear axis, shown as a dotted line) of an array of beam steering elements 108 (e.g., the first array of beam steering elements 108a, the second array of beam steering elements 108b) may be oriented at a non-zero angle with respect to the optical axis of the OCS 100 (e.g., that is aligned with a horizontal direction in FIG. 1A). As a result, spacing variations may be introduced to a set of beams that propagate through the OCS 100. For example, distortions of beam positions of a set of beams emitted by the first array of optical ports 102a may be introduced by non-normal angles of incidence of the set of beams on the first array of beam steering elements 108a, which has a principal axis 109a that is oriented at a non-zero angle (e.g., a non-horizontal angle) with respect to the optical axis of the OCS 100. Similarly, distortions of beam positions of a set of beams exiting from the second array of beam steering elements 108b may be introduced by non-normal angles of emission of the set of beams from the second array of beam steering elements 108b. Additionally, in some implementations, a set of optical elements 106 may magnify spacing variations introduced to a set of beams. For example, a first set of optical elements 106a may magnify distortions of beam positions by directing (e.g., converging) a set of beams on the first array of beam steering elements 108a. Similarly, a second set of optical elements 106b may magnify the distortions of beam positions by directing (e.g., converging) a set of beams on the second array of optical ports 102b.

The OCS 100 may thereby compensate for spacing variations by arranging an array of optical ports 102 in the first pattern and an array of beam steering elements 108 in the second pattern. For example, the first array of optical ports 102 emits a set of beams in the first pattern, and spacing variations are introduced as the set of beams propagate to the first array of beam steering elements 108a. This may occur due to the first array of beam steering elements 108a being oriented at a first non-zero angle with respect to the optical axis of the OCS 100, and, optionally, due to the first set of optical elements 106a converging the set of beams on the first array of beam steering elements 108a. As a result, the set of beams impinge on the first array of beam steering elements 108a in a pattern that matches the second pattern. Additionally, the set of beams may thereafter propagate to, and exit from, the second array of beam steering elements 108b in a pattern that matches the second pattern. Additional spacing variations are then introduced as the set of beams propagate to the second array of optical ports 102b. This may occur due to the second array of beam steering elements 108b being oriented at a second non-zero angle with respect to the optical axis of the OCS 100, and, optionally, due to the second set of optical elements 106b converging the set of beams on the second array of beam steering elements 108b. As a result, the set of beams impinge on the second array of beam steering elements 108b in a pattern that matches the first pattern.

In some implementations, the second array of optical ports 102b is arranged in a third pattern and the second array of beam steering elements 108b is arranged in a fourth pattern that are different than (e.g., do not match) the first pattern and the second pattern, which enables the set of beams to exit from the first array of beam steering elements 108a in a pattern that matches the third pattern. The set of beams may thereafter propagate to, and exit from, the second array of beam steering elements 108b in the pattern that matches the third pattern. Additional spacing variations are then introduced as the set of beams propagate to the second array of optical ports 102b. This may occur due to the second array of beam steering elements 108b being oriented at a second non-zero angle with respect to the optical axis of the OCS 100, and, optionally, due to the second set of optical elements 106b converging the set of beams on the second array of beam steering elements 108b. As a result, the set of beams impinge on the second array of beam steering elements 108b in a pattern that matches the fourth pattern. A particular pattern of the third pattern and the fourth pattern may be a non-periodic pattern and another particular pattern of the third pattern and the fourth pattern may be a periodic pattern.

Thus, each optical port in the first array of optical ports 102a provides light to a respective beam steering element in the first array of beam steering elements 108a, on a one-to-one basis. Similarly, each optical port in the second array of optical ports 102b receives light from a respective beam steering element in the second array of beam steering elements 108b, on a one-to-one basis.

In an example operation of the OCS 100, the first array of optical ports 102a, arranged in a first pattern, provides a set of beams (e.g., beams) to the first array of beam-forming elements 104a, arranged in a pattern that matches the first pattern. The first array of beam-forming elements 104a collimates or focuses the set of beams provided by the first array of optical ports 102a. After collimation or focusing of the set of beams by the first array of beam-forming elements 104a, the set of beams propagate in a pattern that matches the first pattern to the first set of optical elements 106a. The first set of optical elements 106a converge the set of beams on the first array of beam steering elements 108a, which is arranged in a second pattern (e.g., that is different than the first pattern) and has a principal axis 109a that is oriented at a first non-zero angle with respect to the optical axis of the OCS 100. As a result, spacing variations are introduced to the set of beams such that the set of beams impinge on the first array of beam steering elements 108a in a pattern that matches the second pattern. Thus, each beam that emits from an optical port of the first array of optical ports 102a is received by a corresponding beam steering element of the first array of beam steering elements 108a, on a one-to-one basis. This is due to a particular pattern of the first pattern and the second pattern being a non-periodic pattern and another particular pattern of the first pattern and the second pattern being a periodic pattern.

The first array of beam steering elements 108a then directs (e.g., based on a switching configuration) the set of beams. Here, each beam steering element in the first array of beam steering elements 108a directs a beam incident thereon toward a beam steering element in the second array of beam steering elements 108b. As noted above, each beam steering element in the first array of beam steering elements 108a directs the one or more beams incident thereon independently. In some implementations, a beam waist of a given beam in the set of beams is near a midpoint in a region of optical coupling between the first array of beam steering elements 108a and the second array of beam steering elements 108b.

The second array of beam steering elements 108b, which is arranged in a third pattern (e.g., that matches the second pattern, or that is different than the second pattern) and has a principal axis 109b that is oriented at a second non-zero angle with respect to the optical axis of the OCS 100, further directs (e.g., based on the switching configuration) the set of beams after direction by the first array of beam steering elements 108a. Here, each beam steering element in the second array of beam steering elements 108b directs a beam incident thereon toward a beam-forming element in the second array of beam-forming elements 104b. As noted above, each beam steering element in the second array of beam steering elements 108b directs the one or more beams incident thereon independently. After direction by the second array of beam steering elements 108b, the second set of optical elements 106b converge the set of beams on the second array of beam-forming elements 104b. As a result, other spacing variations are introduced to the set of beams such that the set of beams impinge on the second array of beam-forming elements 104b in a fourth pattern (e.g., that matches the first pattern, or that is different than the first pattern).

Thus, the second array of beam-forming elements 104b, which is arranged in the fourth pattern, collimates or focuses the set of beams, and the second array of optical ports 102b, also arranged in the fourth pattern, receives the set of beams after collimation or focusing by the second array of beam-forming elements 104b. Thus, each beam that is directed from a beam steering element of the second array of beam steering elements 108b is received by a corresponding optical port of the second array of optical ports 102b, on a one-to-one basis. This is due to a particular pattern of the third pattern and the fourth pattern being a non-periodic pattern and another particular pattern of the third pattern and the fourth pattern being a periodic pattern.

In the above-described operation of the OCS 100, the set of beams converge onto the first array of beam steering elements 108a, and the principal axis 109a of the first array of beam steering elements 108a is oriented at a first non-zero angle so as to minimize the required beam steering angle of the first array of beam steering elements 108a. Additionally, the principal axis 109b of the second array of beam steering elements 108b is oriented at a second non-zero angle, and the set of beams converge onto the second array of optical ports 102b so as to minimize the required beam steering angle of the second array of beam steering elements 108b. Further, there are no optical elements in a region of optical coupling between the first array of beam steering elements 108a and the second array of beam steering elements 108b, thereby avoiding cross-talk while achieving the benefits described above.

Thus, one advantage of the configuration of the OCS 100 shown in FIG. 1A is that such a configuration reduces a beam steering requirement of the array of beam steering elements 108 (e.g., a total beam steering angle of θ or less is needed). In some implementations, the beam steering requirement for a given array of beam steering elements 108 is approximately equal to one-half of a size of the given array of beam steering elements 108 divided by a distance between the first array of beam steering elements 108a and the second array of beam steering elements 108b. Put another way, the beam steering requirement may be such that, at a rest position (e.g., when a 0 volt (V) control voltage is applied to the beam steering elements of a given array of beam steering elements 108), each beam steering element is to direct a respective beam to approximately a same location on the other array of beam steering elements 108. Another advantage of the configuration of the OCS 100 shown in FIG. 1A is that such a configuration does not require any optical elements in a region of optical coupling between the first array of beam steering elements 108a and the second array of beam steering elements 108b. Therefore, cross-talk between beam paths is avoided (e.g., because no optical elements exist in the region of optical coupling, and therefore no defects in optical surfaces exist in the region of optical coupling to introduce scattering).

FIG. 1B is a diagram illustrating another example implementation of the OCS 100. As shown in FIG. 1B, the OCS 100 may in some implementations include an optical element 112 in a region of optical coupling between the first array of beam steering elements 108a and the second array of beam steering elements 108b. The optical element 112 may be, for example, a lens (e.g., a Fourier lens) or a mirror. Notably, the configuration of the OCS 100 shown in FIG. 1B differs from the configuration of the OCS 100 shown in FIG. 1A in that the set of beams incident on the first array of beam steering elements 108a are parallel, and beam waists are located at the arrays of beam steering elements 108. Thus, optimization conditions for the sets of optical elements 106 in the configuration shown in FIG. 1B are different from those for the configuration shown in FIG. 1A.

One solution is that magnification provided by the first set of optical elements 106a in a region of optical coupling between the first array of optical ports 102a and the first array of beam steering elements 108a is equal to f1/f2, a distance between the first array of optical ports 102a and the optical element 106a1 is equal to f1, a distance between the optical element 106a1 and the optical element 106a2 is equal to f1+f2, and a distance between the optical element 106a2 lens and the first array of beam steering elements 108a is equal to f2, where f1 and f2 are the focal lengths of the optical element 106a1 and the optical element 106a2, respectively. Such a configuration is advantageous in that any fiber position errors in the array of optical ports 102a (which result in beam angle errors after being collimated by the first array of beam-forming elements 104a) can be corrected by adjusting the corresponding beam steering element angles, which can be done during calibration of the OCS 100. Further, the configuration of the OCS 100 in FIG. 1B achieves low insertion loss because the first array of beam steering elements 108a is located at an image of the first array of beam-forming elements 104a, meaning that there will be no additional light lost to beam clipping at the first array of beam steering elements 108a, after a beam has been clipped by the first array of beam-forming elements 104a. In some implementations, the configuration of the OCS 100 including the optical element 112 can be used when, for example, a risk of cross-talk is acceptable or cross-talk can be otherwise controlled or eliminated.

As further shown in FIG. 1B, the set of beams do not converge on the first array of beam steering elements 108a and on the second array of beam steering elements 108b, and thus a set of optical elements 106 (e.g., the first set of optical elements 106a and/or the second set of optical elements 106b) does not enhance spacing variations of the set of beams introduced by non-zero angle orientations of the first array of beam steering elements 108a and the second array of beam steering elements 108b. However, a set of optical elements 106 may introduce distortion, such as pincushion distortion, barrel distortion, or another type of distortion typical to optical elements (e.g., lenses), that contributes to the spacing variations.

As indicated above, FIGS. 1A-1B are provided as an example. Other examples may differ from what is described with regard to FIGS. 1A-1B. The number and arrangement of elements shown in FIGS. 1A-1B are provided as an example. In practice, there may be additional elements, fewer elements, different elements, or differently arranged elements than those shown in FIGS. 1A-1B. Furthermore, two or more elements shown in FIGS. 1A-1B may be implemented within a single element, or a single element shown in FIGS. 1A-1B may be implemented as multiple, distributed elements. For example, an array of optical ports 102 and an array of beam-forming elements 104 may be implemented as a single element. Additionally, or alternatively, a set of elements (e.g., one or more elements) shown in FIGS. 1A-1B may perform one or more functions described as being performed by another set of elements shown in FIGS. 1A-1B.

FIGS. 2A-2B are diagrams of example implementations 200 associated with the OCS 100. FIGS. 2A-2B show examples of a first pattern 202, in which an array of optical ports 102 may be arranged (and in which an array of beam-forming elements 104 may be arranged), and a second pattern 204, in which an array of beam steering elements 108 may be arranged.

FIG. 2A shows a first example implementation 200, where the first pattern 202 is a periodic pattern and the second pattern 204 is a non-periodic pattern. As shown, the first pattern 202 has respective uniform spacings (e.g., a uniform spacing or pitch between elements) in at least two directions. For example, the first pattern 202 has a first uniform spacing in a first direction (e.g., in an x-direction) and a second uniform spacing in a second direction (e.g., in a y-direction). As additionally shown, the second pattern 204 has a non-uniform spacing (e.g., non-uniform spacing or pitch between elements) in at least one direction. For example, the second pattern 204 has a first non-uniform spacing in the first direction (e.g., in the x-direction) and a second non-uniform spacing in the second direction (e.g., in a y-direction).

FIG. 2B shows a second example implementation 200, where the first pattern 202 is a non-periodic pattern and the second pattern 204 is a periodic pattern. As shown, the first pattern 202 has a non-uniform spacing (e.g., non-uniform spacing or pitch between elements) in at least one direction. For example, the first pattern 202 has a first non-uniform spacing in the first direction (e.g., in the x-direction) and a second non-uniform spacing in the second direction (e.g., in a y-direction). As additionally shown, the second pattern 204 has respective uniform spacings (e.g., non-uniform spacing or pitch between elements) in at least two directions. For example, the second pattern 204 has a first uniform spacing in the first direction (e.g., in the x-direction) and a second uniform spacing in the second direction (e.g., in the y-direction).

In this way, when spacing variations are introduced to a set of beams that propagate through the OCS 100, the OCS 100 compensates for the spacing variations by arranging the array of optical ports 102 (and the array of beam-forming elements 104) in the first pattern 202 and the array of beam steering elements 108 in the second pattern 204 (e.g., in either example implementation 200). Accordingly, each optical port in the first array of optical ports 102a provides a beam to a respective beam steering element in the first array of beam steering elements 108a, on a one-to-one basis. Similarly, each optical port in the second array of optical ports 102b receives a beam from a respective beam steering element in the second array of beam steering elements 108b, on a one-to-one basis.

As indicated above, FIGS. 2A-2B are provided as an example. Other examples may differ from what is described with regard to FIGS. 2A-2B.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”). Further, spatially relative terms, such as “below,” “lower,” “above,” “upper,” and the like, may be used herein for ease of description to describe one element or feature's relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

What is claimed is:

1. An optical circuit switch (OCS), comprising:
a first array of optical ports arranged in a first pattern;
a first array of beam steering elements arranged in a second pattern; and
a first set of optical elements positioned between the first array of optical ports and the first array of beam steering elements, wherein:
the first array of optical ports are optically coupled to the first array of beam steering elements by the first set of optical elements,
a particular pattern of the first pattern and the second pattern is a non-periodic pattern, and
another particular pattern of the first pattern and the second pattern is a periodic pattern.

2. The OCS of claim 1, wherein the particular pattern has a uniform spacing in a first direction and a non-uniform spacing in a second direction.

3. The OCS of claim 1, wherein the particular pattern has a first non-uniform spacing in a first direction and a second non-uniform spacing in a second direction.

4. The OCS of claim 1, wherein a principal axis of the first array of beam steering elements is oriented at a non-zero angle with respect to an optical axis of the OCS.

5. The OCS of claim 4, wherein the first set of optical elements are configured to direct a set of beams emitted by the first array of optical ports to the first array of beam steering elements, and
wherein the first set of optical elements are further configured to converge the set of beams on the first array of beam steering elements.

6. The OCS of claim 1, further comprising:
a second array of optical ports arranged in a third pattern;
a second array of beam steering elements arranged in a fourth pattern; and
a second set of optical elements positioned between the second array of optical ports and the second array of beam steering elements, wherein:
the first array of beam steering elements is optically coupled to the second array of beam steering elements,
the second array of beam steering elements is optically coupled to the second array of optical ports by the second set of optical elements,
a particular pattern of the third pattern and the fourth pattern is a non-periodic pattern, and
another particular pattern of the third pattern and the fourth pattern is a periodic pattern.

7. The OCS of claim 6, wherein a principal axis of the first array of beam steering elements is oriented at a first non-zero angle with respect to an optical axis of the OCS and the second array of beam steering elements is oriented at a second non-zero angle with respect to the optical axis,
wherein the first non-zero angle is different than the second non-zero angle.

8. The OCS of claim 6, wherein the second set of optical elements are configured to direct a set of beams that exit from the second array of beam steering elements to the second array of optical ports, and
wherein the second set of optical elements are further configured to converge the set of beams on the second array of optical ports.

9. The OCS of claim 6, further comprising:
a third set of optical elements positioned between the first array of beam steering elements and the second array of beam steering elements and configured to direct a set of beams that exit from the first array of beam steering elements to the second array of beam steering elements.

10. An optical switch, comprising:
an array of optical ports arranged in a first pattern; and
an array of beam steering elements arranged in a second pattern, wherein:
the array of optical ports are optically coupled to the array of beam steering elements,
a particular pattern of the first pattern and the second pattern is a non-periodic pattern, and
another particular pattern of the first pattern and the second pattern is a periodic pattern.

11. The optical switch of claim 10, wherein:
the particular pattern has a first uniform spacing in a first direction and a non-uniform spacing in a second direction, and
the other particular pattern has a second uniform spacing in the first direction and a third uniform spacing in the second direction.

12. The optical switch of claim 10, wherein:
the particular pattern has a first non-uniform spacing in a first direction and a second non-uniform spacing in a second direction, and
the other particular pattern has a first uniform spacing in the first direction and a second uniform spacing in the second direction.

13. The optical switch of claim 10, wherein a principal axis of the array of beam steering elements is oriented at a non-zero angle with respect to an optical axis of the optical switch.

14. The optical switch of claim 10, further comprising:
a set of optical elements positioned between the array of optical ports and the array of beam steering elements and configured to direct a set of beams between the array of optical ports and the array of beam steering elements.

15. The optical switch of claim 14, wherein the set of optical elements are configured to converge the set of beams on the array of beam steering elements.

16. An optical device, comprising:
an array of optical ports; and
an array of beam steering elements optically coupled to the array of optical ports, wherein:
one array of the array of optical ports and the array of beam steering elements is arranged in a non-periodic pattern, and
another array of the array of optical ports and the array of beam steering elements is arranged in a periodic pattern.

17. The optical device of claim 16, wherein:
the non-periodic pattern has a non-uniform spacing in a particular direction, and
the periodic pattern has a uniform spacing in the particular direction.

18. The optical device of claim 16, wherein:
the non-periodic pattern has respective non-uniform periodicities in a plurality of directions, and
the periodic pattern has respective uniform periodicities in the plurality of directions.

19. The optical device of claim 16, wherein a principal axis of the array of beam steering elements is oriented at a non-zero angle with respect to an optical axis of the optical device.

20. The optical device of claim 16, further comprising:
a set of optical elements positioned between the array of optical ports and the array of beam steering elements.
